(19) United States
(12) Patent Application Publication
(10) Pub. No.: US 2008/0105872 A1
(43) Pub. Date: May 8, 2008

(54) PIXEL STRUCTURE

(75) Inventors: Meng-Chi Liou, Taoyuan County (TW); Chia-Chuan Pu, Taipei City (TW); Chien-Yin Peng, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: CHUNGHWA PICTURE TUBES, LTD., Taipei (TW)

(21) Appl. No.: 11/549,125

(22) Filed: Oct. 13, 2006

(51) Int. Cl. H01L 29/04

(52) U.S. Cl. 257/59

(57) ABSTRACT

A pixel structure is provided. A scan line is disposed on a substrate and a gate insulating layer is disposed thereon. A semiconductor layer is disposed on the gate insulating layer and a data line, a source electrode and a drain electrode are disposed thereon. The source electrode and the drain electrode are located above the scan line. The source electrode is connected to the data line. A semiconductor layer exposed by the source electrode and the drain electrode is a channel region. The source electrode protrudes from the channel region along the length direction of the channel region. A passivation layer covers the substrate. A pixel electrode is disposed on the passivation layer and electrically connected to the drain electrode via a contact opening of the passivation layer.

### BACKGROUND OF THE INVENTION

1. Field of Invention

The present invention relates to a pixel structure, and more particularly to a pixel structure formed by four mask processes.

2. Description of Related Art

The rapid progress of the multimedia society is mainly promoted by the significant progress of semiconductor element or human-computer display device. As for the displaying device, Cathode Ray Tube (CRT) has superior displaying quality and is also economic, which occupies the recent displaying device market. However, as for the environment for a person to operate a plurality of terminals/displaying devices on the desk, or in view of the environmental protection, if it is predicted from the trend of saving energy, CRT has many problems about space utilization and power consumption, which cannot provide an effective solution for the requirements of being light, thin, short and small, and with lower power consumption. Therefore, the thin film transistor liquid crystal display (TFT-LCD) with advantages of high definition, high space utilization, lower power consumption and radiation free, has become the mainstream of the market.

To enhance the competitiveness at the market, the manufacture must exert their efforts to reduce the manufacturing cost of the TET-LCD. Generally, the manufacturing procedures of the pixel structure are simplified, so as to reduce the manufacturing cost, and the number of masks used therein is also reduced, so as to effectively reduce the manufacturing cost. The conventional five-mask process and four-mask process are described below.

FIG. 1A is a top view of a conventional pixel structure, FIG. 1B is a sectional view of FIG. 1A along the cross-sectional line I-I′. Referring to FIG. 1A and FIG. 1B simultaneously, the pixel structure comprises a substrate 10, a scan line 12, a gate insulating layer 14, a semiconductor layer 16, a data line 18a, a source electrode 18b, a drain electrode 18c, a passivation layer 20 and a pixel electrode 22. The scan line 12 is disposed on the substrate 10, and the gate insulating layer 14 covers the scan line 12. The semiconductor layer 16 is disposed on the gate insulating layer 14, and located above the scan line 12. The data line 18a is disposed on the gate insulating layer 14, and the source electrode 18b and the drain electrode 18c are disposed on the semiconductor layer 16. The passivation layer 20 covers the scan line 12, the gate insulating layer 14, the semiconductor layer 16, the data line 18a, the source electrode 18b and the drain electrode 18c. In addition, the pixel electrode 22 is disposed on the passivation layer 20 and electrically connected to the drain electrode 18c. Briefly speaking, this conventional pixel structure is formed by a five-mask process. In addition, as for this conventional pixel structure, the scan line 12 is taken as a gate, so as to enhance the Aperture Ratio of the pixel structure. As the number of the masks increases, the cost is correspondingly increased, therefore, a four-mask process is provided in the conventional art for manufacturing the pixel structure, which is described below in detail.

FIG. 2A is a top view of another conventional pixel structure, FIG. 2B is a sectional view of FIG. 2A along the cross-sectional line II-II′. Referring to FIG. 2A and FIG. 2B simultaneously, the pixel structure is substantially the same as that of FIG. 1A and FIG. 1B, thus, the same elements are represented by the same referential numerals. However, the difference there-between lies in that, the patterns of the semiconductor layer 16, the data line 18a, the source electrode 18b and the drain electrode 18c of the pixel structure in FIGS. 2A and 2B are defined by the same half tone mask, such that the process for manufacturing this pixel structure requires four masks. In other words, the semiconductor layer 16 is distributed below the data line 18a, the source electrode 18b and the drain electrode 18c. In addition, the semiconductor layer 16 exposed by the source electrode 18b and the drain electrode 18c is a channel region 16a. It should be noted that the edge 16a′ of the channel region 16a′ is substantially aligned with the edge 18c′ of the drain electrode 18c. In other words, the shrinkage phenomenon should not occur at the edge of the channel region 16a.

However, more particularly, since the photo-resist is optically exposed and baked unevenly, such that the shrinkage phenomenon occurs at the edge 16a′, that is, the edge 16a′ cannot be aligned with the edge 18c′. In other words, the edge 16a′ of the channel region 16a is asymmetric with the edge 16a″, thus, as for this conventional pixel structure, electric problems such as higher leakage current or uneven leakage current occur.

### SUMMARY OF THE INVENTION

An objective of the present invention is to provide a pixel structure, so as to alleviate the problem of relative high leakage current or on-current non-uniformity.

Another objective of the present invention is to provide a pixel structure having preferred electrical quality.

To achieve the above or other objectives, the present invention provides a pixel structure, which comprises a substrate, a scan line, a gate insulating layer, a semiconductor layer, a data line, a source electrode, a drain electrode, a passivation layer and a pixel electrode. The scan line is disposed on the substrate. The gate insulating layer covers the scan line and the substrate. The semiconductor layer is disposed on the gate insulating layer. The data line is disposed on the semiconductor layer. The source electrode and the drain electrode are disposed on the semiconductor layer, and located above the scan line, and the source electrode is connected to the data line. The semiconductor layer exposed by the source electrode and the drain electrode is a channel region, wherein the source electrode protrudes from the channel region along the length direction of the channel region. The passivation layer covers the data line, the source electrode, the drain electrode, the semiconductor layer and the gate insulating layer, and the passivation layer has a contact opening for exposing a part of the drain electrode. The pixel electrode is disposed on the passivation layer and electrically connected to the drain electrode via the contact opening.

To achieve the above or other objectives, the present invention further provides a pixel structure, which comprises a substrate, a scan line, a gate insulating layer, a semiconductor layer, a data line, a source electrode, a drain electrode, a passivation layer and a pixel electrode. The scan line is disposed on the substrate. The gate insulating layer covers the scan line and the substrate. The semiconductor layer is disposed on the gate insulating layer. The data line is disposed on the semiconductor layer. The source electrode and the drain electrode are disposed on the semiconductor layer and located above the scan line. The source electrode is connected to the data line, and the semiconductor layer exposed by the source electrode and the drain electrode is a channel region, wherein the source electrode protrudes towards the channel region along the width direction of the channel region. The passivation layer covers the data line, the source electrode, the drain electrode, the semiconductor layer and the gate insulating layer. The passivation layer has a contact opening for exposing a part of the drain electrode. The pixel electrode is disposed on the passivation layer and electrically connected to the drain electrode via the contact opening.

In an embodiment of the present invention, the above channel region can be rectangular.

In an embodiment of the present invention, the edge of the above channel region is aligned with the edge of the drain electrode.

In an embodiment of the present invention, the above data line, the source electrode, the drain electrode and the semiconductor layer are defined by a half tone mask, a slit mask, or a stacked layers mask.

In an embodiment of the present invention, the above half tone mask includes a transparent substrate, a transmittance modulation layer and a light shielding layer. The transmittance modulation layer is disposed on the transparent substrate, and the transmittance modulation layer has at least one opening, and the position of the opening is relative to the position of the channel region. The light shielding layer is disposed on the transmittance modulation layer, and the pattern of the light shielding layer corresponds to the pattern of the data line, the source electrode and the drain electrode.

In view of the above, since special source electrode pattern (the source electrode protrudes from the channel region along the length direction of the channel region or protrudes towards the channel region along the width direction) is used in the four-mask process of the present invention, the shrinkage phenomenon of the channel region is alleviated, thereby reducing the leakage current.

In order to make the aforementioned and other objects, features and advantages of the present invention comprehensible, preferred embodiments accompanied with figures are described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a top view of a conventional pixel structure.

FIG. 1B is a sectional view taken along the cross-sectional line I-I′ of FIG. 1A.

FIG. 2A is a top view of another conventional pixel structure.

FIG. 2B is a sectional view taken along the cross-sectional line II-II′ of FIG. 2A.

FIGS. 3A-3C are schematic top views of the process for manufacturing the pixel structure according to a first embodiment of the present invention.

FIGS. 4A-4C are sectional views taken along the cross-sectional line III-III′ of FIGS. 3A-3C.

FIG. 5 is a top view of the half tone mask in FIG. 3A.

FIG. 6A is a top view of the pixel structure according to a second embodiment of the present invention.

FIG. 6B is a sectional view taken along the cross-sectional line IV-IV′ of FIG. 6A.

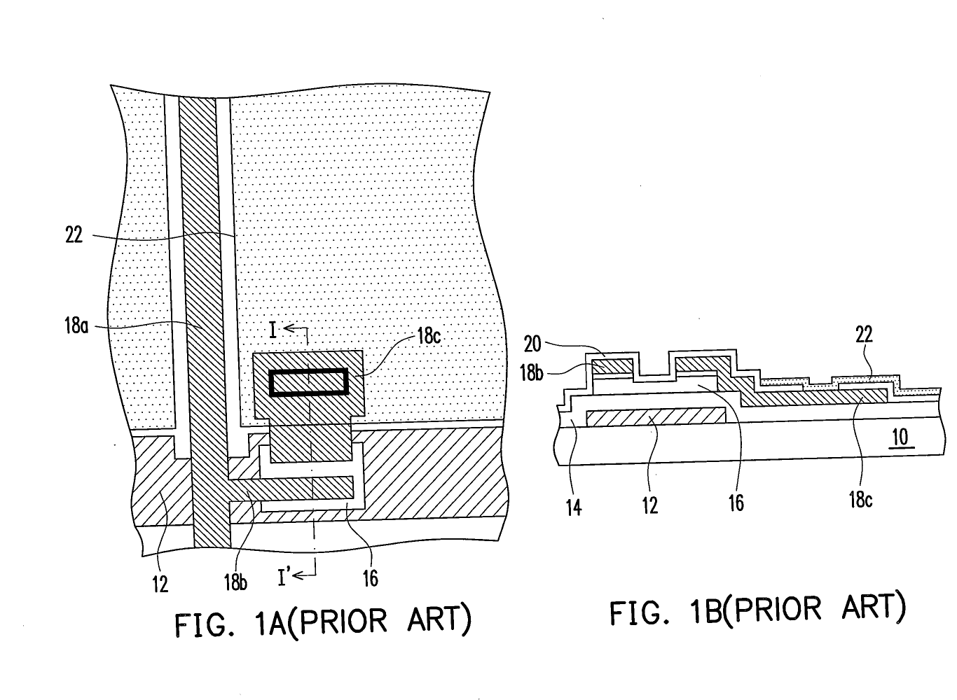

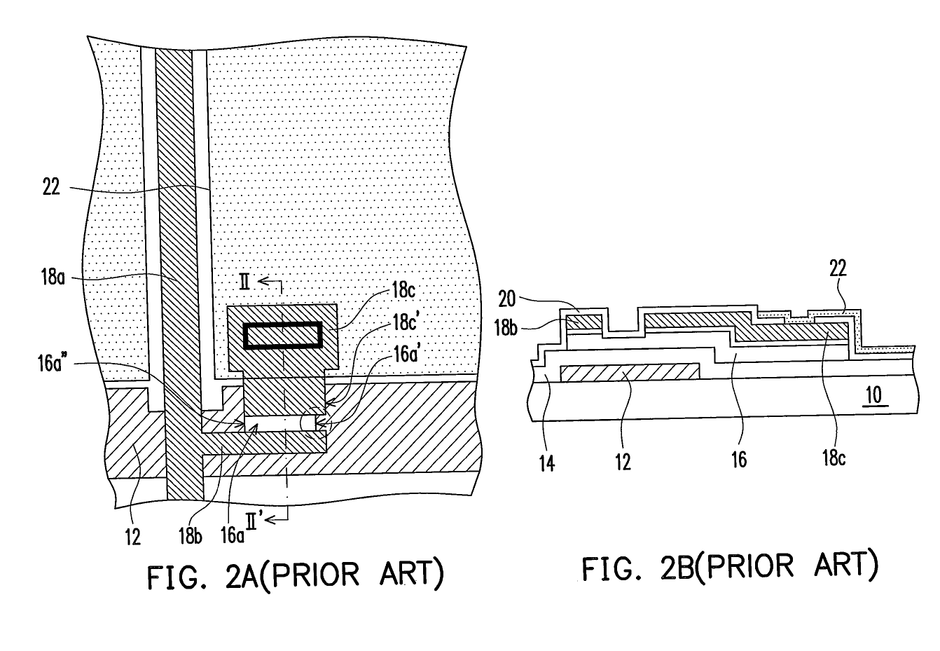

### DESCRIPTION OF EMBODIMENTS

A common process for manufacturing a pixel structure through four masks uses a half tone mask to define the data line, the source electrode, the drain electrode and the semiconductor layer at the same time. The semiconductor layer exposed by the source electrode and the drain electrode is a channel region. However, in the conventional four-mask process, shrinkage problem occurs at the edge of the channel region, therefore, the present invention provides a special source electrode pattern, so as to alleviate the shrinkage phenomenon occurred at the edge of the channel region by the four-mask process. Particularly, the source electrode in the present invention protrudes from the channel region along the length direction of the channel region, or protrudes towards the channel region along the width direction of the channel region, so as to alleviate the shrinkage phenomenon occurred at the edge of the channel region.

The pixel structure and the method for manufacturing the same are described below through a first embodiment of the present invention, and then another pixel 20 structure is also described through a second embodiment of the present invention.

### First Embodiment

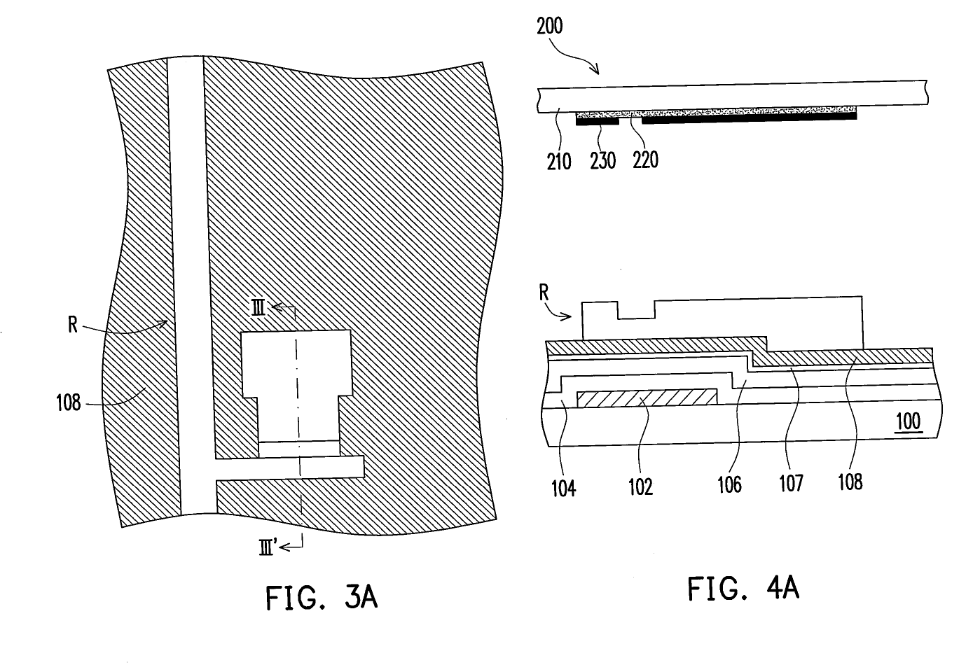

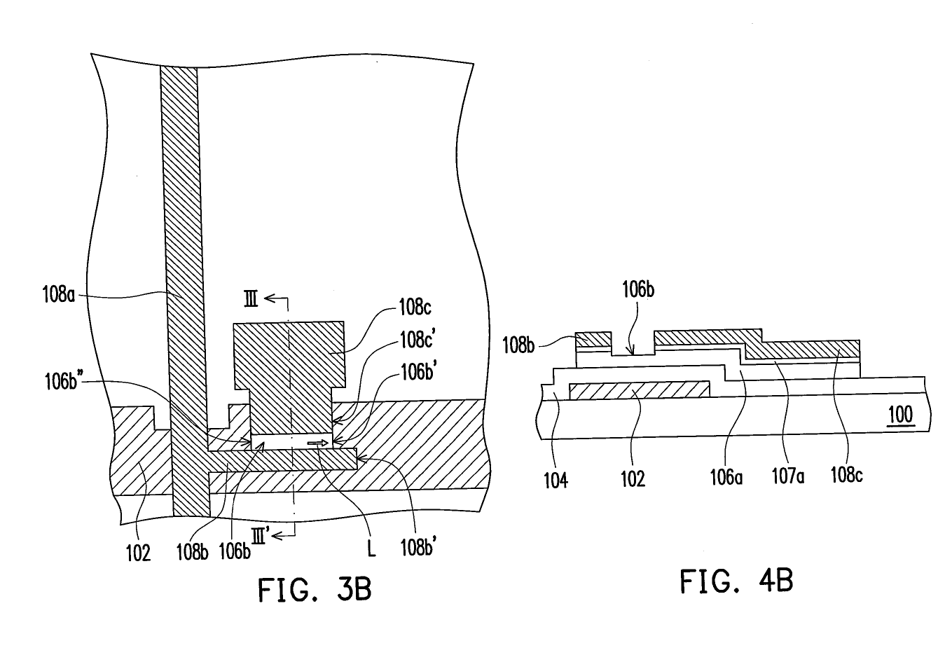

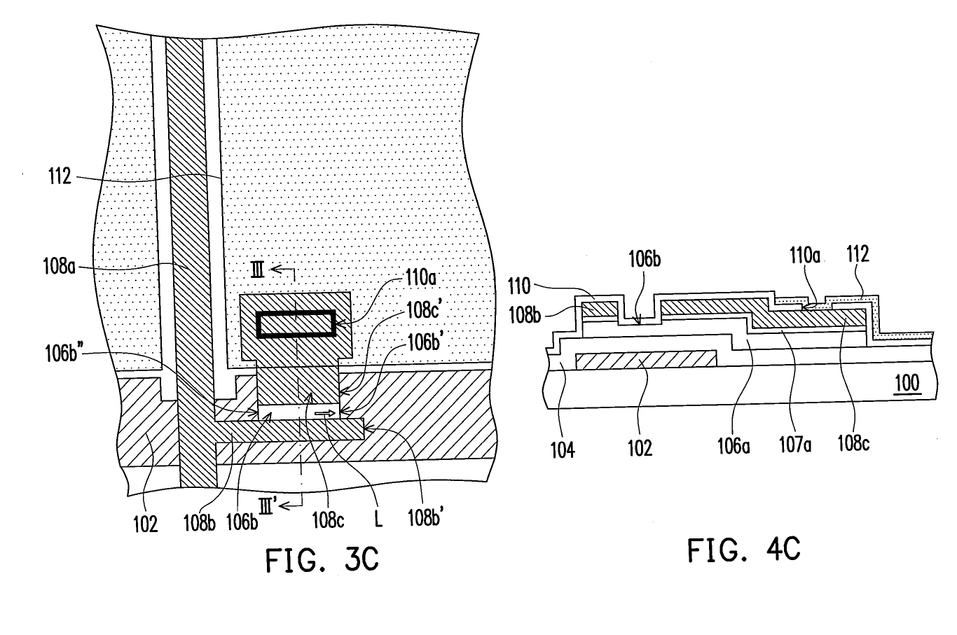

FIGS. 3A-3C are schematic top views of the process for manufacturing the pixel structure according to a first embodiment of the present invention. FIGS. 4A-4C are sectional views taken along the cross-sectional line III-III′ in FIGS. 3A-3C. Referring to FIG. 3A and FIG. 4A simultaneously, the method for manufacturing the pixel structure of the present invention comprises the following steps. A substrate 100 is provided. Next, a scan line 102 and a gate insulating layer 104 are sequentially formed on the substrate 100, wherein the gate insulating layer 104 covers the scan line 102. Then, a semiconductor material layer 106 and a conductive layer 108 are sequentially formed on the substrate 100. In this embodiment, after the semiconductor material layer 106 is formed, an ohmic contact material layer 107 is further formed in the semiconductor material layer 106 by doping process. Then, a half tone mask 200 is provided. A patterned photoresist layer R is formed on the conductive layer 108 by using the half tone mask 200, and the pattern photoresist layer R has more than two kinds of thickness distribution.

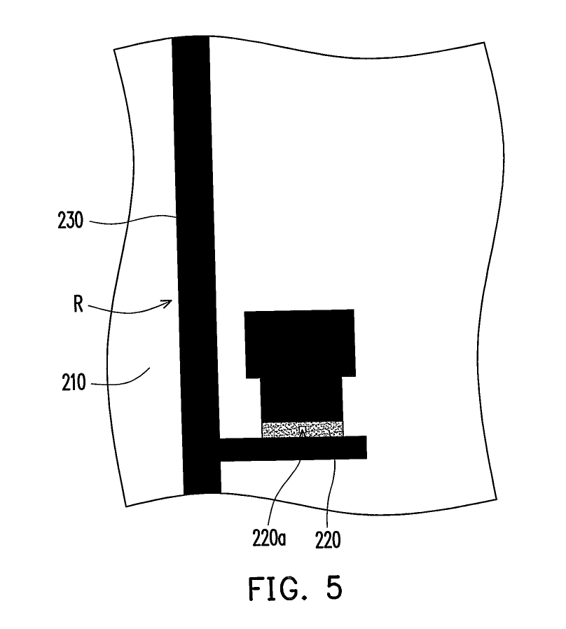

FIG. 5 is a top view of the half tone mask in FIG. 3A. Referring to FIG. 3A and FIG. 5 simultaneously, more particularly, the half tone mask 200 includes a transparent substrate 210, a transmittance modulation layer 220 and a light shielding layer 230, wherein the transmittance modulation layer 220 is disposed on the transparent substrate 210, the light shielding layer 230 is disposed on the transmittance modulation layer 220, and the pattern of the light shielding layer 230 corresponds to the pattern of a data line 108a, a source electrode 108b and a drain electrode 108c. In this embodiment, to increase the exposure quality in a channel region 106b, the transmittance modulation layer 220 has at least one opening 220a, and the position of the opening 220a is relative to the position of the channel region 106b. Therefore, the transmittance of the opening 220a region is larger than other region. Although the opening 220a is at the center of the channel region 106b, the sharp, position and numbers of the opening 220a is not limited to the embodiment described. Furthermore, a slit mask, a stacked layers mask or another mask with two kinds of transmittances can also be used to replace the half tone mask 200.

Then, referring to FIGS. 3B and 4B simultaneously, a part of the conductive layer 108, a part of the ohmic contact material layer 107 and a part of the semiconductor material layer 106 are removed by using the pattern photoresist layer R as a mask, and meanwhile a semiconductor layer 106a, an ohmic contact layer 107a, the data line 108a, the source electrode 108b and the drain electrode 108c are formed. The data line 108a is disposed on the semiconductor layer 106a. The source electrode 108b and the drain electrode 108c are disposed on the semiconductor layer 106a and located above the scan line 102, wherein the source electrode 108b is connected to the data line 108a. In addition, the method for removing a part of each of the above layers is, for example, dry etching process. The semiconductor layer 106a exposed by the source electrode 108b and the drain electrode 108c is the channel region 106b. Then, the patterned photoresist layer R is removed.

Then, referring to FIG. 3C and FIG. 4C simultaneously, a passivation layer 110 is formed above the substrate 100. The passivation layer 110 has a contact opening 110a for exposing the drain electrode 108c. After that, a pixel electrode 112 is formed on the passivation layer 110 and is electrically connected to the drain electrode 108c via the contact opening 110a.

Particularly, in this embodiment, the channel region 106b shown in FIG. 3C is rectangular, and the source electrode 108b extends along the length direction L of the channel region 106b, that is, the source electrode 108b extends along the scan line 102. In other words, the edge 108b′ of the source electrode 108b protrudes from the edge 106b′ of the channel region 106b. For example, the extending direction of the source electrode 108b is not restricted to be parallel to that of the scan line 102, and the both can form an angle. In addition, since the source electrode 108b is extended outwards from the edge 106b′, when defining the patterns of the semiconductor layer 106a and the source electrode 108b, the problem of shrinkage does not easily occur at the edge 106b′ of the channel region 106b.

More particularly, since the special pattern of the source electrode 108b changes the diffraction characteristics of the light, the uneven exposure or baking problem does not easily occur at the above patterned photoresist layer R, that is, the edge 106b′ is ensured to be aligned with the edge 108c′ of the drain electrode 108c. In other words, the edge 106b″ of the channel region 106b is symmetric with the edge 106b′. Thus, the shape of the channel region 106b is consistent with the predetermined shape, so as to alleviate the phenomenon such as the relative high leakage current or the uneven leakage current.

Another pixel structure of the present invention is described below through the second embodiment, which can also be used for alleviating the shrinkage problem at the edge of the channel region.

### Second Embodiment

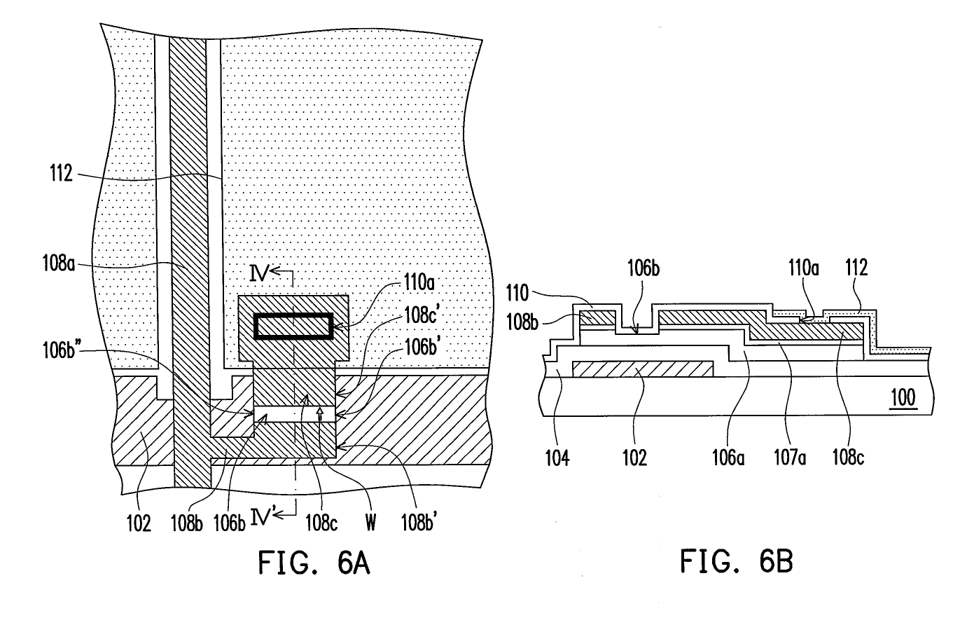

FIG. 6A is a top view of a pixel structure according to a second embodiment of the present invention, FIG. 6B is a sectional view taken along the cross-sectional line IV-IV′ of FIG. 6A. In the second embodiment, the same elements are represented with the same referential numerals as those of the first embodiment, and the repeated content is omitted, but only the differences from that of the first embodiment are described.

Referring to FIG. 6A and FIG. 6B simultaneously, in this embodiment, the channel region 106b shown in FIG. 6A is rectangular, and the source electrode 108b protrudes towards the channel region 106b along the width direction W of the channel region 106b, that is, the extending direction of the source electrode 108b is perpendicular to that of the scan line 102. However, the extending direction of the source electrode 108b in this embodiment can also form an angle with that of the scan line 102.

Since the source electrode 108b protrudes towards the channel region 106b, the uneven exposure or baking problem does not easily occur for the patterned photoresist layer used for defining the semiconductor layer 106a and the source electrode 108b, that is, the edge 106b′ is ensured to be aligned with the edge 108c′ of the drain electrode 108c. In other words, both sides of the channel region 106b are relatively symmetric with each other, so as to alleviate the electric problems such as relative high leakage current or uneven leakage current.

Similarly, as mentioned in the above embodiment, in order to increase the exposure quality in the channel region 106b, the transmittance modulation layer of the half tone mask for defining the source electrode 108b and the drain electrode 108c can also has least one opening, and the position of the opening is relative to the position of the channel region (similar to that shown in FIG. 5).

In summary, the source electrode in the present invention protrudes from the channel region along the length direction of the channel region, or protrudes towards the channel region along the width direction of the channel region, such that the uneven exposure or baking problem does not easily occur for the patterned photoresist layer used for defining the semiconductor layer and the source electrode, thus alleviating the phenomenon that both sides of the channel region are asymmetric. In other words, the shrinkage phenomenon does not easily occur at the edge of the channel region, such that the electric problems such as relative high leakage current or uneven leakage current are alleviated.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A pixel structure, comprising:
a substrate;
a scan line, disposed on the substrate;
a gate insulating layer, covering the scan line and the substrate;
a semiconductor layer, disposed on the gate insulating layer;
a data line, disposed on the semiconductor layer;
a source electrode and a drain electrode, disposed on the semiconductor layer, located above the scan line, wherein the source electrode is connected to the data line, the semiconductor layer exposed by the source electrode and the drain electrode is a channel region, and the source electrode protrudes from the channel region along the length direction of the channel region and extends along the scan line, wherein the semiconductor layer is disposed underneath the data line. the source electrode and the drain electrode;
a passivation layer, covering the data line, the source electrode, the drain electrode, the semiconductor layer and the gate insulating layer, and having a contact opening for exposing a part of the drain electrode; and
a pixel electrode, disposed on the passivation layer, and electrically connected to the drain electrode via the contact opening.

2. The pixel structure as claimed in claim 1, wherein the channel region is rectangular.

3. The pixel structure as claimed in claim 1, wherein the edge of the semiconductor layer at the channel region is aligned with the edge of the drain electrode.

4. The pixel structure as claimed in claim 1, wherein the data line, the source electrode, the drain electrode and the semiconductor layer are defined by utilizing a half tone mask, a slit mask or a stacked layers mask.

5. The pixel structure as claimed in claim 4, wherein the half tone mask comprises:
a transparent substrate;
a transmittance modulation layer, disposed on the transparent substrate, and having at least one opening, and the position of the opening is relative to the position of the channel region; and
a light shielding layer, disposed on the transmittance modulation layer, and having a pattern corresponding to that of the data line, the source electrode and the drain electrode.

6-10. (canceled)

11. The pixel structure as claimed in claim 1, wherein the edge of the source electrode protrudes from the edge of the channel region.
